(19) United States
(12) Patent Application Publication
(10) Pub. No.: US 2026/0261467 A1
(43) Pub. Date: Sep. 3, 2026

(54) SYSTEM AND METHOD FOR PROVIDING MULTIPLE BANDWIDTH SUPPORT USING A FREQUENCY SHIFTER

(71) Applicant: JIO PLATFORMS LIMITED, Ahmedabad, Gujarat (IN)

(72) Inventors: Vinod Kumar SINGH, Navi Mumbai, Maharashtra (IN); Veera Sai Satyanarayana Prasad MARNI, Navi Mumbai, Maharashtra (IN); Santhi Swaroop CHINNAM, Palangi, Andhra Pradesh (IN); Gayathri R NAIR, Thiruvananthapuram, Kerala (IN); Aayush BHATNAGAR, Navi Mumbai, Maharashtra (IN); Pradeep Kumar BHATNAGAR, Navi Mumbai, Maharashtra (IN)

(73) Assignee: JIO PLATFORMS LIMITED, Ahmedabad, Gujarat (IN)

(21) Appl. No.: 18/880,022

(22) PCT Filed: Aug. 30, 2023
(86) PCT No.: PCT/IB2023/058568

§ 371 Date: Dec. 30, 2024

(30) Foreign Application Priority Data
Aug. 31, 2022 (IN) 202221049807

(51) Int. Cl. H04L 27/26

(52) U.S. Cl. CPC H04L 27/2614; H04L 27/2634; H04L 27/26524

(57) ABSTRACT

The present disclosure relates to a system and method of providing multiple bandwidth support by incorporating one additional frequency shifter in a Field Programmable Gate Array (FPGA) platform while re-using available base band design with single Fast Fourier Transform (FFT) size. This method facilitates to save FPGA resources and provides additional sampling in lower bandwidth configurations leading to common sampling rate for all bandwidths which further simplifies an end-to-end design. Further, the method discloses an efficient way of implementing a frequency shifter in the FPGA platform.

### RESERVATION OF RIGHTS

A portion of the disclosure of this patent document contains material, which is subject to intellectual property rights such as but are not limited to, copyright, design, trademark, integrated circuit (IC) layout design, and/or trade dress protection, belonging to Jio Platforms Limited (JPL) or its affiliates (hereinafter referred as owner). The owner has no objection to the facsimile reproduction by anyone of the patent document or the patent disclosure, as it appears in the Patent and Trademark Office patent files or records, but otherwise reserves all rights whatsoever. All rights to such intellectual property are fully reserved by the owner.

### FIELD OF INVENTION

The embodiments of the present disclosure generally relate to wireless communication technology. In particular, the present disclosure relates to systems and methods for providing multiple bandwidth support using a frequency shifter.

### BACKGROUND

The following description of the related art is intended to provide background information pertaining to the field of the disclosure. This section may include certain aspects of the art that may be related to various features of the present disclosure. However, it should be appreciated that this section is used only to enhance the understanding of the reader with respect to the present disclosure, and not as admissions of the prior art.

Wireless communication systems such as a fifth generation (5G) new radio (NR) includes multiple bandwidth options ranging from 5 Megahertz (MHz) to 100 MHz in a frequency range 1 (FR1) and 50 MHz to 400 MHz in a frequency range 2 (FR2). Implementing multiple bandwidth support over a field programmable gate array (FPGA) platform requires an additional effort, where some of the existing blocks may be redesigned and additional blocks may be appended. However, this implementation may increase FPGA resource consumption within a baseband.

Further, wireless communication system standards provide multiple bandwidth options such that operators may have flexibility in deploying base stations spanning a spectrum bandwidth acquired by them. For example, in a fourth generation (4G) network, a channel bandwidth option defined may include 1.4, 3, 5, 10, 15 and 20 MHz. Similarly, in a 5G new radio NR, channel bandwidth options may be defined with 30 KHz subcarrier spacing for frequency range 1 (FR1) in the ranges 5, 10, 15, 20, 25, 30, 40, 50, 60, 70, 80, 90 and 100 MHz and in the ranges 50, 100, 200, and 400 MHz for frequency range 2 (FR2). Also, operators may be required to support configurable bandwidth in the base station such that the base station deployed in a field may operate at the allocated spectrum of interest in each region. Implementation of multiple bandwidth support in a digital signal processing (DSP) architecture-based solution may require only change in application programming interfaces (APIs) or corresponding configurations. However, implementation of the same in the FPGA platform may require an additional effort in redesigning and reconfiguring of existing blocks. Further, additional blocks may be added and thus, an increase in the FPGA resource consumption within the baseband may be observed. For example, if a typical 5G NR FR1 system designed in FPGA may be designed for 100 MHz with FFT size of 4096, then changing the same to support other possible bandwidths may require changes like changing the FFT size ranging from 256 to 4096. These changes not only increase FPGA resources but also render a complex system design.

There is, therefore, a need in the art to provide a system and a method that can mitigate the problems associated with the prior arts.

### OBJECTS OF THE INVENTION

Some of the objects of the present disclosure, which at least one embodiment herein satisfies are listed herein below.

It is an object of the present disclosure to provide a system and a method where multiple bandwidth support is provided by just adding one additional frequency shifter module in a field programmable gate array (FPGA) platform.

It is an object of the present disclosure to provide a system and a method where the frequency shifter module is introduced in time domain after an Inverse Fast Fourier Transform (iFFT) during a downlink transmission and prior to a Fast Fourier Transform (FFT) during an uplink reception.

It is an object of the present disclosure to provide a system and a method where a feed configured bandwidth is provided as an input to the frequency shifter module such that the frequency domain position of the starting subcarrier is shifted to a required location.

It is an object of the present disclosure to provide a system and a method where a uniform sampling rate is maintained for all bandwidths to simplify an end-to-end design.

### SUMMARY

This section is provided to introduce certain objects and aspects of the present disclosure in a simplified form that are further described below in the detailed description. This summary is not intended to identify the key features or the scope of the claimed subject matter.

In an aspect, the present disclosure relates to a system supporting multiple bandwidth. The system includes a processor, and a memory operatively coupled to the processor, where the memory stores instructions to be executed by the processor. The processor generates one or more samples from one or more subcarriers using an Inverse Fast Fourier Transform (IFFT) technique during a modulation stage and using a Fast Fourier Transform (FFT) technique during a de-modulation stage. The processor computes one or more phase coefficients associated with the one or more subcarriers. The processor augments the one or more samples with the one or more phase coefficients to generate a time domain frequency shift associated with the one or more samples for transmission and reception.

In an embodiment, the processor may use a complex multiplier to augment the one or more samples with the one or more phase coefficients during the modulation and de-modulation stages.

In an embodiment, the processor may utilize a feed configured bandwidth associated with the one or more phase coefficients to generate the time domain frequency shift associated with the one or more samples for transmission and reception.

In an embodiment, the time domain frequency shift may facilitate to support one or more bandwidths associated with the one or more subcarriers.

In an embodiment, the processor may generate a quadrant symmetry associated with the one or more phase coefficients to reduce a storage requirement associated with the one or more phase coefficients.

In an embodiment, the quadrant symmetry may be based on an in phase and a quadrature component of the one or more subcarriers.

In an embodiment, the processor may maintain a uniform sampling rate across the one or more bandwidths associated with the one or more subcarriers.

In an aspect, the present disclosure relates to a method for supporting multiple bandwidth. The method includes generating, by a processor associated with a system, one or more samples from one or more subcarriers using an IFFT technique during a modulation stage and using a Fast Fourier Transform (FFT) technique during a de-modulation stage. The method includes computing, by the processor, one or more phase coefficients associated with the one or more subcarriers. The method includes augmenting, by the processor, the one or more samples with the one or more phase coefficients to generate a time domain frequency shift associated with the one or more samples for transmission and reception.

In an embodiment, the method may include using, by the processor, a complex multiplier to augment the one or more samples with the one or more phase coefficients during the modulation and de-modulation stages.

In an embodiment, the method may include utilizing, by the processor, a feed configured bandwidth associated with the one or more phase coefficients to generate the time domain frequency shift associated with the one or more samples for transmission and reception.

In an embodiment, the method may include generating, by the processor, a quadrant symmetry associated with the one or more phase coefficients to reduce a storage requirement associated with the one or more phase coefficients.

In an embodiment, the quadrant symmetry may be based on an in phase and a quadrature component of the one or more subcarriers.

In an embodiment, the method may include maintaining, by the processor, a uniform sampling rate across the one or more bandwidths associated with the one or more subcarriers.

In an aspect, a user equipment (UE) includes one or more processors communicatively coupled to a processor in a system. The one or more processors are coupled with a memory and said memory stores instructions to be executed by the one or more processors. The one or more processors augment one or more modulated samples to generate a time domain frequency shift associated with the one or more modulated samples, compute one or more phase coefficients associated with one or more subcarriers in response to the generation of the time domain frequency shift, and generate one or more samples from the one or more subcarriers using an IFFT technique during a modulation stage and Fast Fourier Transform technique during a demodulation stage.

In an aspect, a non-transitory computer readable medium includes a processor with executable instructions that cause the processor to generate one or more samples from one or more subcarriers using an IFFT technique during a modulation stage and FFT during a de-modulation stage. The processor computes one or more phase coefficients associated with the one or more subcarriers. The processor augments the one or more samples with the one or more phase coefficients to generate a time domain frequency shift associated with the one or more samples for transmission and reception.

### BRIEF DESCRIPTION OF DRAWINGS

The accompanying drawings, which are incorporated herein, and constitute a part of this disclosure, illustrate exemplary embodiments of the disclosed methods and systems which like reference numerals refer to the same parts throughout the different drawings. Components in the drawings are not necessarily to scale, emphasis instead being placed upon clearly illustrating the principles of the present disclosure. Some drawings may indicate the components using block diagrams and may not represent the internal circuitry of each component. It will be appreciated by those skilled in the art that disclosure of such drawings includes the disclosure of electrical components, electronic components, or circuitry commonly used to implement such components.

FIG. 1 illustrates an example network architecture (100) for implementing a proposed system (108), in accordance with an embodiment of the present disclosure.

FIG. 2 illustrates an example block diagram (200) of a proposed system (108), in accordance with an embodiment of the present disclosure.

FIG. 3 illustrates a block diagram (300) of a baseband transmitter and receiver.

FIG. 4 illustrates an example block diagram (400) of a baseband transmitter and receiver incorporating a time domain frequency shifter, in accordance with an embodiment of the present disclosure.

FIG. 5 illustrates a block diagram (500) of a system architecture of a hybrid time-frequency domain physical random access channel (PRACH) receiver.

FIG. 6 illustrates an example block diagram (600) of a module level system architecture incorporating the time domain frequency shifter, in accordance with an embodiment of the present disclosure.

FIG. 7 illustrates an example computer system (700) in which or with which embodiments of the present disclosure may be implemented.

The foregoing shall be more apparent from the following more detailed description of the disclosure.

### DETAILED DESCRIPTION

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The ensuing description provides exemplary embodiments only and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the disclosure as set forth.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail to avoid obscuring the embodiments.

Also, it is noted that individual embodiments may be described as a process that is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

The word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive in a manner similar to the term “comprising” as an open transition word without precluding any additional or other elements.

Reference throughout this specification to “one embodiment” or “an embodiment” or “an instance” or “one instance” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terminology used herein is for the purpose of describing particular embodiments only and is not intended to be limiting of the disclosure. As used herein, the singular forms “a”, “an”, and “the” are intended to include the plural forms as well, unless the context indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Orthogonal Frequency Division Multiplexing (OFDM) may be a transmission system used for various types of digital transmission. The OFDM method makes highly efficient use of frequencies by frequency-multiplexing a plurality of narrowband digitally-modulated signals using mutually-orthogonal sub-carriers. Further, OFDM may divide the available spectrum into multiple narrow sub-channels to be transmitted in parallel. Since each sub-channel has a much lower data rate compared to the overall data rate, a multipath process may be improved. At the same time, interference between each sub-channel may be eliminated by ensuring that the carrier frequency of each sub-channel is orthogonal to every other sub-channel. This may be achieved by selecting sub-carriers to be a “frequency bin” used within an Inverse Fast Fourier Transform (iFFT) where incoming data may be mapped to a point for each sub-carrier. The iFFT may be used to convert the frequency domain OFDM symbol into N time domain samples where N may be the size of the iFFT that may be used.

The present disclosure provides multiple bandwidth support by just adding one additional frequency shifter in a Field Programmable Gate Array (FPGA) platform. Further, the proposed solution re-uses the same based band design without modifications. This approach not only saves FPGA resources but provides additional sampling in lower bandwidth configurations leading to a common sampling rate for all bandwidths. Therefore, the proposed solution provides an end-to-end design and an efficient way for implementing the frequency shifter in the FPGA platform.

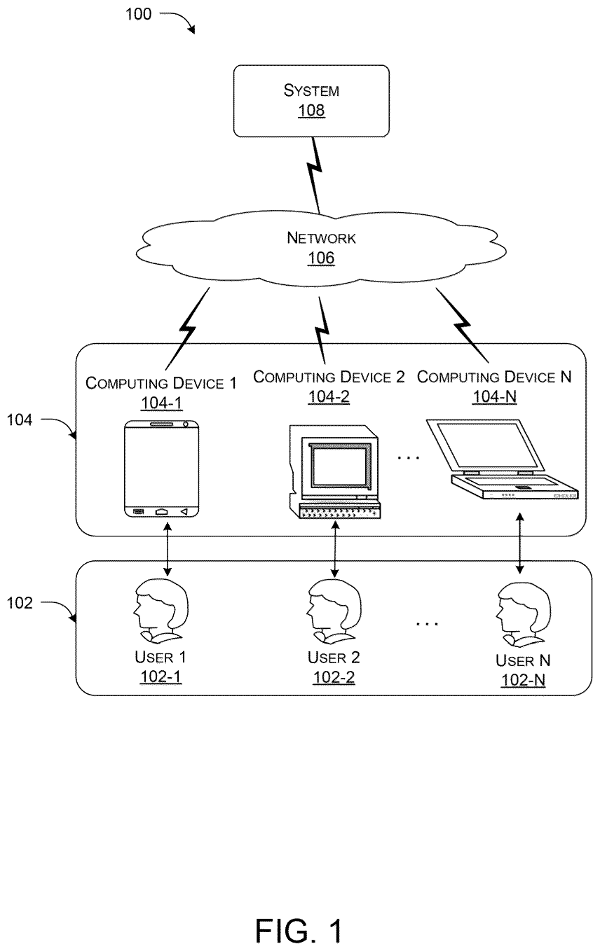

FIG. 1 illustrates an example network architecture (100) for implementing a proposed system (108), in accordance with an embodiment of the present disclosure.

As illustrated in FIG. 1, the network architecture (100) may include a system (108). The system (108) may be connected to one or more computing devices (104-1, 104-2 . . . 104-N) via a network (106). The one or more computing devices (104-1, 104-2 . . . 104-N) may be interchangeably specified as a user equipment (UE) (104) and be operated by one or more users (102-1, 102-2 . . . 102-N). Further, the one or more users (102-1, 102-2 . . . 102-N) may be interchangeably referred as a user (102) or users (102).

In an embodiment, the computing devices (104) may include, but not be limited to, a mobile, a laptop, etc. Further, the computing devices (104) may include a smartphone, virtual reality (VR) devices, augmented reality (AR) devices, a general-purpose computer, desktop, personal digital assistant, tablet computer, and a mainframe computer. Additionally, input devices for receiving input from the user (102) such as a touch pad, touch-enabled screen, electronic pen, and the like may be used. A person of ordinary skill in the art will appreciate that the computing devices (104) may not be restricted to the mentioned devices and various other devices may be used.

In an embodiment, the network (106) may include, by way of example but not limitation, at least a portion of one or more networks having one or more nodes that transmit, receive, forward, generate, buffer, store, route, switch, process, or a combination thereof, etc. one or more messages, packets, signals, waves, voltage or current levels, some combination thereof, or so forth. The network (106) may also include, by way of example but not limitation, one or more of a wireless network, a wired network, an internet, an intranet, a public network, a private network, a packet-switched network, a circuit-switched network, an ad hoc network, an infrastructure network, a Public-Switched Telephone Network (PSTN), a cable network, a cellular network, a satellite network, a fiber optic network, or some combination thereof.

In an embodiment, the system (108) during downlink transmission may generate one or more samples from one or more subcarriers using an iFFT technique during a modulation stage. Further, the system (108) may use a complex multiplier to augment the one or more samples with the one or more phase coefficients during the modulation stage.

In an embodiment, the system (108) may compute one or more phase coefficients associated with the one or more subcarriers. The system (108) may utilize a feed configured bandwidth associated with the one or more phase coefficients to generate the time domain frequency shift associated with the one or more samples for transmission.

In an embodiment, the system (108) may augment the one or more samples with the one or more phase coefficients to generate the time domain frequency shift associated with the one or more samples for transmission. Further, the time domain frequency shift may be configured to support one or more bandwidths associated with the one or more subcarriers.

Further, in an embodiment, the system (108) may generate a quadrant symmetry associated with the one or more phase coefficients to reduce a storage requirement associated with the one or more phase coefficients. The quadrant symmetry may be based on an in phase and a quadrature component of the one or more subcarriers.

In an embodiment, a Digital Front End (DFE) module may be configured in the system (108) that incorporates a common up/down sampling of half band filters for different bandwidth configurations.

In an embodiment, the system (108) may maintain a uniform sampling rate across the one or more bandwidths associated with the one or more subcarriers.

In downlink at the receiver side, the computing device (104) may augment the one or more modulated samples to generate a time domain frequency shift associated with the one or more modulated samples. Further, the computing device (104) may compute one or more phase coefficient associated with one or more subcarriers. Furthermore, the computing device (104) may generate one or more samples from the one or more subcarriers using an FFT technique during the demodulation stage.

Similarly in uplink, the computing device (104) may augment the one or more samples with the one or more phase coefficients to generate the time domain frequency shift associated with the one or more samples for transmission. Further, the time domain frequency shift may be configured to support one or more bandwidths associated with the one or more subcarriers.

In uplink at the receiver side, the system (108) may augment the one or more modulated samples to generate a time domain frequency shift associated with the one or more modulated samples. Further, the system (108) may compute one or more phase coefficient associated with one or more subcarriers. Furthermore, the system (108) may generate one or more samples from the one or more subcarriers using an FFT technique during the demodulation stage.

Although FIG. 1 shows exemplary components of the network architecture (100), in other embodiments, the network architecture (100) may include fewer components, different components, differently arranged components, or additional functional components than depicted in FIG. 1. Additionally, or alternatively, one or more components of the network architecture (100) may perform functions described as being performed by one or more other components of the network architecture (100).

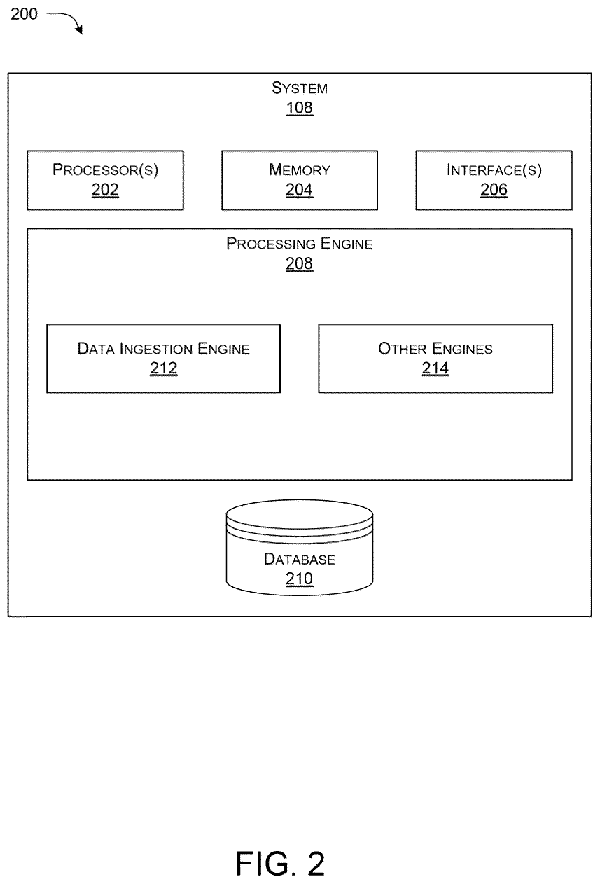

FIG. 2 illustrates an example block diagram (200) of a proposed system (108), in accordance with an embodiment of the present disclosure.

Referring to FIG. 2, the system (108) may comprise one or more processor(s) (202) that may be implemented as one or more microprocessors, microcomputers, microcontrollers, digital signal processors, central processing units, logic circuitries, and/or any devices that process data based on operational instructions. Among other capabilities, the one or more processor(s) (202) may be configured to fetch and execute computer-readable instructions stored in a memory (204) of the system (108). The memory (204) may be configured to store one or more computer-readable instructions or routines in a non-transitory computer readable storage medium, which may be fetched and executed to create or share data packets over a network service. The memory (204) may comprise any non-transitory storage device including, for example, volatile memory such as random-access memory (RAM), or non-volatile memory such as erasable programmable read only memory (EPROM), flash memory, and the like.

In an embodiment, the system (108) may include an interface(s) (206). The interface(s) (206) may comprise a variety of interfaces, for example, interfaces for data input and output (I/O) devices, storage devices, and the like. The interface(s) (206) may also provide a communication pathway for one or more components of the system (108). Examples of such components include, but are not limited to, processing engine(s) (208) and a database (210), where the processing engine(s) (208) may include, but not be limited to, a data ingestion engine (212) and other engine(s) (214). In an embodiment, the other engine(s) (214) may include, but not limited to, a data management engine, an input/output engine, and a notification engine.

In an embodiment, the processing engine(s) (208) may be implemented as a combination of hardware and programming (for example, programmable instructions) to implement one or more functionalities of the processing engine(s) (208). In examples described herein, such combinations of hardware and programming may be implemented in several different ways. For example, the programming for the processing engine(s) (208) may be processor-executable instructions stored on a non-transitory machine-readable storage medium and the hardware for the processing engine(s) (208) may comprise a processing resource (for example, one or more processors), to execute such instructions. In the present examples, the machine-readable storage medium may store instructions that, when executed by the processing resource, implement the processing engine(s) (208). In such examples, the system (108) may comprise the machine-readable storage medium storing the instructions and the processing resource to execute the instructions, or the machine-readable storage medium may be separate but accessible to the system (108) and the processing resource. In other examples, the processing engine(s) (208) may be implemented by electronic circuitry.

In an embodiment, the processor (202) may receive an input via the data ingestion engine (212). The input may be received from a computing device associated with one or more users (102). The input may be based one or more subcarriers associated with the computing device (104). The processor (202) may store the input in the database (210).

In an embodiment, the processor (202) may generate one or more samples from the one or more subcarriers using an iFFT technique during a modulation stage and using a FFT technique during a de-modulation stage. Further, the processor (202) may use a complex multiplier to augment the one or more samples with the one or more phase coefficients during the modulation and de-modulation stages.

In an embodiment, the processor (202) may compute one or more phase coefficients associated with the one or more subcarriers. The processor (202) may utilize a feed configured bandwidth associated with the one or more phase coefficients to generate the time domain frequency shift associated with the one or more samples for transmission and reception.

In an embodiment, the processor (202) may augment the one or more samples with the one or more phase coefficients to generate the time domain frequency shift associated with the one or more samples for transmission and reception. Further, the time domain frequency shift may be configured to support one or more bandwidths associated with the one or more subcarriers.

Further, in an embodiment, the processor (202) may generate a quadrant symmetry associated with the one or more phase coefficients to reduce a storage requirement associated with the one or more phase coefficients. The quadrant symmetry may be based on an in phase and a quadrature component of the one or more subcarriers.

In an embodiment, the processor (202) may maintain a uniform sampling rate across the one or more bandwidths associated with the one or more subcarriers.

Although FIG. 2 shows exemplary components of the system (108), in other embodiments, the system (108) may include fewer components, different components, differently arranged components, or additional functional components than depicted in FIG. 2. Additionally, or alternatively, one or more components of the system (108) may perform functions described as being performed by one or more other components of the system (108).

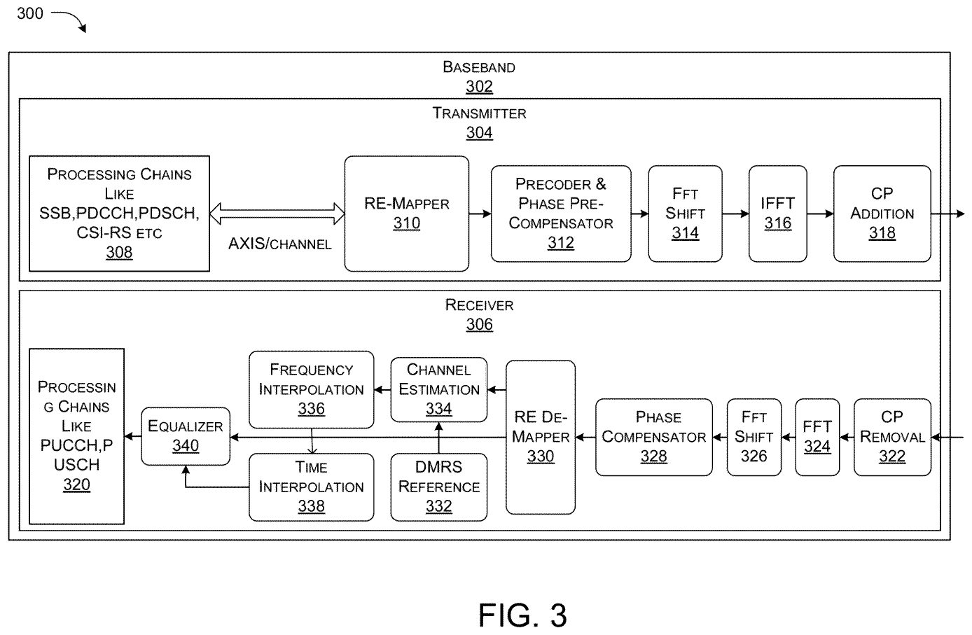

FIG. 3 illustrates a block diagram (300) of a current baseband transmitter and receiver.

As illustrated in FIG. 3, a baseband (302) may include a transmitter (304) and a receiver (306). Processing chains (308) including, but not limited to, a synchronization signal block (SSB), a physical downlink control channel (PDCCH), a physical downlink shared channel (PDSCH), and a channel state information-reference signal (CSI-RS) may be provided to a resource element (RE) mapper (310) in the transmitter (304). Further, the RE mapper (310) output may be provided to a precoder and a phase pre-compensator (312). Further, output from the precoder and the phase pre-compensator (312) may be provided to a Fast Fourier Transform (FFT) shift module (314) and subsequently to an iFFT module (316). Further, an output from the iFFT module (316) may be provided with cyclic prefix (CP) addition (318) during an uplink transmission.

Further, the receiver (306) may include processing chains such as, but not limited to, a physical uplink shared channel (PUSCH)/physical uplink control channel (PUCCH) (320). Output generated during transmission may include CP removal (322) followed by the FFT module (324). Further, an output from the FFT module (324) may be provided to the FFT shift module (326). Further, an output from the FFT shift module (326) may undergo phase compensation using a phase compensator module (328). Output from the phase compensator module (328) may be provided to a RE de-mapper (330) and further to a demodulation reference signal (DMRS) reference module (332). An output from the DMRS module (332) may be provided to a channel estimation module (334), a frequency interpolation module (336), and a time interpolation module (338). Further, an output form the time interpolation module (338) may be provided to an equalizer module (340) and further provided to the processing chains (320) during a downlink transmission.

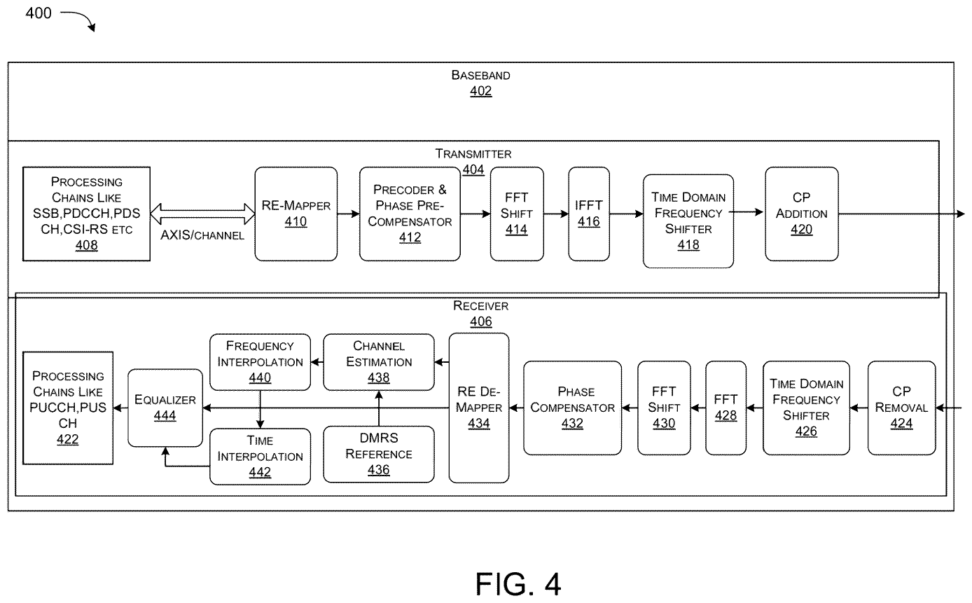

FIG. 4 illustrates an example block diagram (400) of a baseband transmitter and receiver incorporating a time domain frequency shifter, in accordance with an embodiment of the present disclosure.

As illustrated in FIG. 4, in an embodiment, a system (e.g., 108) may provide multiple bandwidth support to one or more subcarriers by implementing an additional frequency shifter in the FPGA platform.

As illustrated in FIG. 4, a baseband (402) may include a transmitter (404) and a receiver (406). Processing chains (408) including, but not limited to, a SSB, a PDCCH, a PDSCH, and a CSI-RS may be provided via an axis/channel to a RE mapper (410) in the transmitter (404). Further, the RE mapper (410) output may be provided to a precoder and a phase pre-compensator (412). Further, an output from the precoder and the phase pre-compensator (412) may be provided to a FFT shift module (414) and subsequently to an iFFT module (416). Further, an output from the iFFT module (416) may be provided to a time domain frequency shifter (418) followed by CP addition (420) during uplink transmission.

Further, in an embodiment, the receiver (406) may include processing chains such as, but not limited to, a PUSCH/PUCCH (422). Output generated during transmission may include CP removal (424) followed by a time domain frequency shifter module (426). Further, an output from the time domain frequency shifter module (426) may be provided to the FFT module (428). Further, an output from the FFT module (428) may be provided to the FFT shift module (430). Further, an output from the FFT shift module (430) may undergo phase compensation using a phase compensator module (432). Output from the phase compensator module (432) may be provided to a RE de-mapper (434) and further to a DMRS reference module (436). Output from the DMRS module (436) may be provided to a channel estimation module (438), a frequency interpolation module (440), and a time interpolation module (442). Further, an output form the time interpolation module (442) may be provided to an equalizer module (444) and provided to the processing chains (422) during downlink transmission.

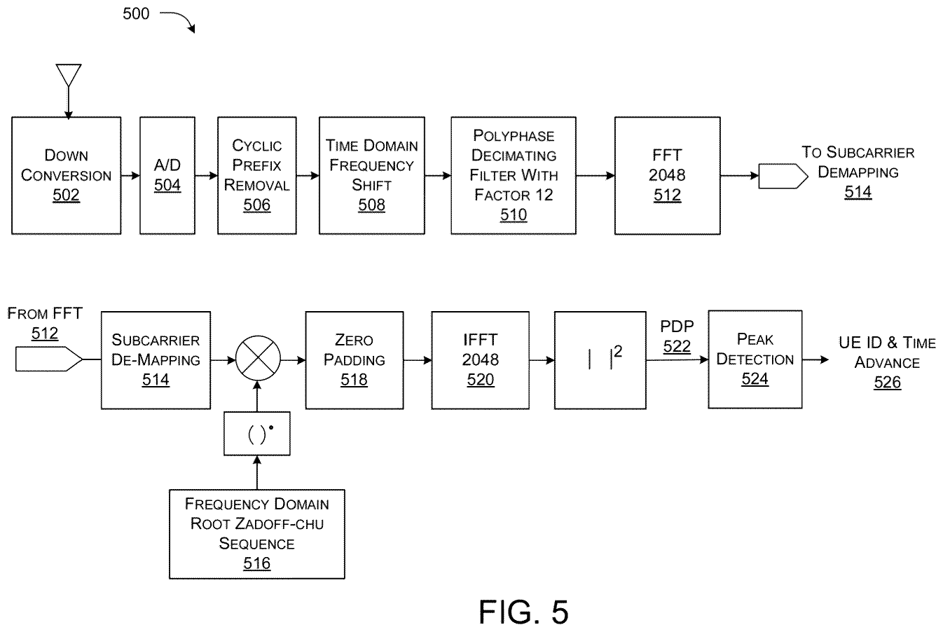

FIG. 5 illustrates a block diagram (500) of a current system architecture of a hybrid time-frequency domain physical random access channel (PRACH) receiver.

5G NR may operate in two frequency ranges FR1 (sub 6 GHz) and FR2 (milli meter wave) with flexible sub carrier spacing ranging from 15 KHz to 480 KHz. Each sub-carrier spacing option may include different transmission bandwidth options and also result in different OFDM symbol durations (number of slots per subframe) as shown in Table 1.

TABLE 1

| | | | | Max | |
|---|---|---|---|---|---|
| | | | Max | Channel | |
| Frequency | SCS | Slots Per | FFT | Bandwidth | Applicable Channel |
| Range | (kHz) | Subframe | Size | (MHz) | Bandwidths (MHz) |
| FR1 | 15 | 1 | 4096 | 50 | 5, 10, 15, 20, 25, |
| | | | | | 30, 40, 50 |
| | 30 | 2 | 4096 | 100 | 5, 10, 15, 20, 25, |
| | | | | | 30, 40, 50, 60, 70, |
| | | | | | 80, 90, 100 |
| | 60 | 4 | 4096 | 100 | 10, 15, 20, 25, 30, |
| | | | | | 40, 50, 60, 70, 80, |
| | | | | | 90, 100 |
| FR2 | 60 | 4 | 4096 | 200 | 50, 100, 200 |
| | 120 | 8 | 4096 | 400 | 50, 100, 200, 400 |

As shown, considering 30 KHz sub carrier spacing as an example, a standard defined multiple bandwidth option may vary from 5 MHz to 100 MHz. With each possible bandwidth, the standard may also provide corresponding FFT sizes and sampling rates as shown in Table 2.

TABLE 2

| | Channel Bandwidth | | CP length for | Sampling Rate |
|---|---|---|---|---|
| | (MHz) for 30 KHz | | symbols 1-13 | Mega Samples |
| | Subcarrier Spacings | FFT | in FFT | Per Second |
| S. No. | (SCS) in FR1 | Size | samples | (Msps) |
| 1 | 5 | 256 | 18 | 7.68 |
| 2 | 10 | 512 | 36 | 15.36 |
| 3 | 15 | 768 | 54 | 23.04 |
| 4 | 20 | 1024 | 72 | 30.72 |
| 5 | 25 | 1024 | 72 | 30.72 |
| 6 | 30 | 1536 | 108 | 46.08 |
| 7 | 40 | 2048 | 144 | 61.44 |
| 8 | 50 | 2048 | 144 | 61.44 |
| 9 | 60 | 3072 | 216 | 92.16 |
| 10 | 70 | 3072 | 216 | 92.16 |
| 11 | 80 | 4096 | 288 | 122.88 |
| 12 | 90 | 4096 | 288 | 122.88 |
| 13 | 100 | 4096 | 288 | 122.88 |

A physical layer in 5G NR may include various physical channels in the downlink (from a base station to the UE (104)) and the uplink (from the UE (104) to base station). The downlink physical channels may include:
Synchronization or broadcast channels-SSB (primary synchronization signal (PSS), secondary synchronization signal (SSS), physical broadcast channel (PBCH))
Control channels—PDCCH
Data channels—PDSCH

Similarly, the uplink physical channels may include:
Access channel—physical random access channel (PRACH)
Control channels—PUCCH
Data Channels—PUSCH

A base station may transmit information like SSB and system information block 1 (SIB1) (using the PDCCH and the PDSCH) and the UE (104) may synchronize and acquire minimum required information to initiate connectivity with the network (106). The first physical channel used by the UE (104) to establish the connection with the network (106) may include the PRACH. The base station receiver may detect the PRACH signal. Typically, the start location of PRACH within the spectrum may be configurable and designing a high pass filter for each possible location of PRACH to remove unwanted frequencies may be complex process. In this case, a conventional method may use a frequency shifter to shift the PRACH location to a center frequency and further use a low pass filter (agnostic to the PRACH location) as shown in FIG. 5.

As illustrated in FIG. 5, a hybrid time-frequency domain PRACH receiver (at the UE (104)) may include down conversion (502) of an input followed by an analog to digital conversion (A/D) (504). The input may include a component from the SSB and the S1B1. Further, the input may undergo a cyclic prefix removal (506) and a time domain frequency shift (508). Further, the input may undergo a polyphase decimating filter with factor 12 (510). Further, the input may go through a FFT (e.g., 2048) (512) and may be provided with a subcarrier de-mapping (514). Further, the input may be integrated with a frequency domain root Zadoff-Chu sequence (516) and may be further provided with a zero padding (518). After the zero padding (518), the input may undergo an IFFT (e.g., 2048) (520) and a packet data protocol (PDP) process (522). Further, the input may undergo a peak detection process (524) and may be further provided with a UE identification (ID) and a time advance (526).

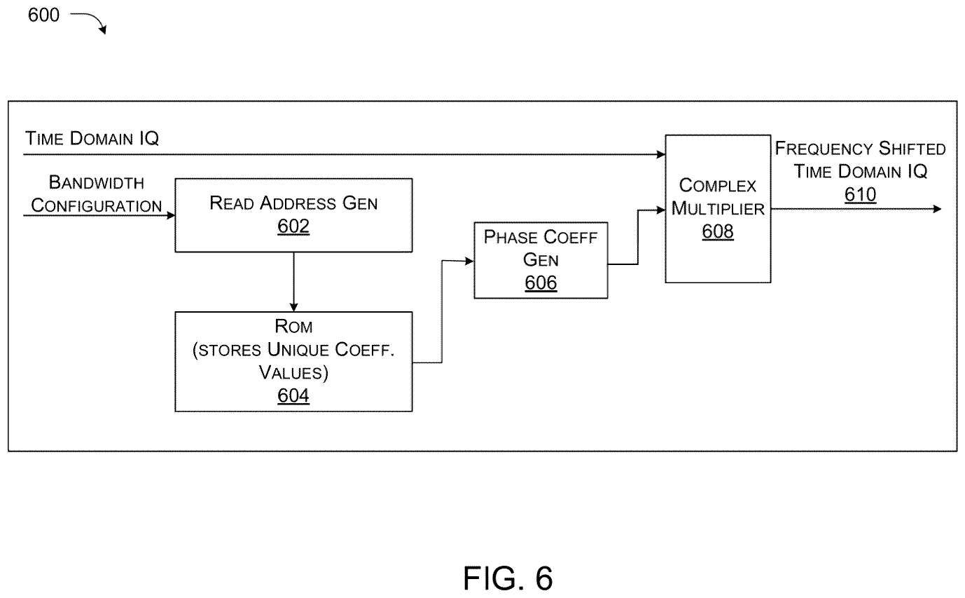

FIG. 6 illustrates an example block diagram (600) of a module level system architecture incorporating the time domain frequency shifter, in accordance with an embodiment of the present disclosure.

In an embodiment, for implementing multiple bandwidth support in the FPGA platform (for example, a Xilinx's Zync radio frequency system on-chip (RFSoC) XCZU28DR), a Xilinx FPGA platform XCZU28DR may be used with the following resources:
930K System Logic Cells
850K co-operative load balancing (CLB) Flip-Flops (FFs)
425K CLB lookup tables (LUTs)
4K DSP Slices
38 Mb Block RAM (1080 BRAMs with 36 Kb each), 22 Mb Ultra RAM (80 URAMs)

In an embodiment, the system (108) may use a frequency shifting property of Fourier Transform. To shift a starting subcarrier in the frequency domain, the time domain samples may be multiplied with phase coefficient equivalent to the required frequency shift. The proposed frequency shifter module may be boot-time configurable to support multiple channel bandwidths associated with the one or more subcarriers. The phase coefficients corresponding to the multiple channel bandwidths may be pre calculated and stored in an internal memory of the system (108). Time domain samples may be collected from an iFFT output in the downlink (or from the FFT input in the uplink) and may be fed to a complex multiplier. Time domain samples may be multiplied with its corresponding phase coefficients as shown in FIG. 6. The resulting product may include a time domain version of the frequency shifted samples.

As illustrated in FIG. 6, bandwidth configurations may be provided to read address generator block (602) in the system (108) and further stored in a read only memory (ROM) (604) of the system (108). Further, the bandwidth configurations may be provided to a phase coefficient generator block (606) and further provided to a complex multiplier block (608). Additionally, a time domain in phase and quadrature (IQ) signal may be provided to the complex multiplier block (608), where the bandwidth configurations may be multiplied with the phase coefficients to generate a frequency shifted time domain IQ (610) for transmission and reception.

In an embodiment, since the intention is to re-use the same sampling rate, a number of time domain samples per symbol may remain as 4096 irrespective of the bandwidth configured. Therefore, 4096×N phase coefficients may be stored which may correspond to N different bandwidth configurations (for example, from 40 to 90 MHz, where the value of N will be 6). But, such a design may consume a large memory space as big as 22 BRAMs for 6 different bandwidths. As an objective to reduce the memory utilization, in an embodiment, the system (108) may utilize a quadrant symmetry process associated with the phase coefficients. With this approach, the storage requirement may be reduced from ⅛^{th} to 1/32^{th} for the phase coefficients depending on the bandwidth configuration. The remaining phase values may be generated by referring to the quadrant. In this way, memory consumption may be reduced from 22 BRAMs to 2 BRAMs. Further, the system (108) may be configured to optimize usage of FPGA resources that may include but not limited to LUTs, FFs and BRAMs, while making use of the underutilized DSP resources. Further, the system (108) may work with a maximum clock frequency up to 491.52 MHz.

Further, in an example embodiment, Table 3 represents resource consumption of the proposed time domain frequency shifter (418, 426) described in FIG. 4.

TABLE 3

| LUT | FF | BRAM | DSP |
|---|---|---|---|
| 384 | 927 | 2 | 12 |

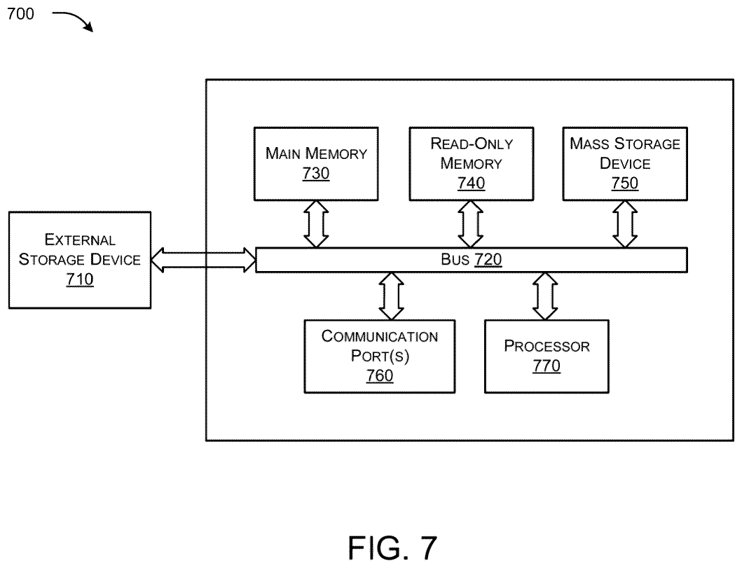

FIG. 7 illustrates an exemplary computer system (700) in which or with which embodiments of the present disclosure may be implemented.

As shown in FIG. 7, the computer system (700) may include an external storage device (710), a bus (720), a main memory (730), a read-only memory (740), a mass storage device (750), a communication port(s) (760), and a processor (770). A person skilled in the art will appreciate that the computer system (700) may include more than one processor and communication ports. The processor (770) may include various modules associated with embodiments of the present disclosure. The communication port(s) (760) may be any of an RS-232 port for use with a modem-based dialup connection, a 10/100 Ethernet port, a Gigabit or 10 Gigabit port using copper or fiber, a serial port, a parallel port, or other existing or future ports. The communication ports(s) (760) may be chosen depending on a network, such as a Local Area Network (LAN), Wide Area Network (WAN), or any network to which the computer system (700) connects.

In an embodiment, the main memory (730) may be Random Access Memory (RAM), or any other dynamic storage device commonly known in the art. The read-only memory (740) may be any static storage device(s) e.g., but not limited to, a Programmable Read Only Memory (PROM) chip for storing static information e.g., start-up or basic input/output system (BIOS) instructions for the processor (770). The mass storage device (750) may be any current or future mass storage solution, which can be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces).

In an embodiment, the bus (720) may communicatively couple the processor(s) (770) with the other memory, storage, and communication blocks. The bus (720) may be, e.g. a Peripheral Component Interconnect PCI)/PCI Extended (PCI-X) bus, Small Computer System Interface (SCSI), (USB), or the like, for connecting expansion cards, drives, and other subsystems as well as other buses, such a front side bus (FSB), which connects the processor (770) to the computer system (700).

In another embodiment, operator and administrative interfaces, e.g., a display, keyboard, and cursor control device may also be coupled to the bus (720) to support direct operator interaction with the computer system (700). Other operator and administrative interfaces can be provided through network connections connected through the communication port(s) (760). Components described above are meant only to exemplify various possibilities. In no way should the aforementioned exemplary computer system (700) limit the scope of the present disclosure.

While considerable emphasis has been placed herein on the preferred embodiments, it will be appreciated that many embodiments can be made and that many changes can be made in the preferred embodiments without departing from the principles of the disclosure. These and other changes in the preferred embodiments of the disclosure will be apparent to those skilled in the art from the disclosure herein, whereby it is to be distinctly understood that the foregoing descriptive matter is to be implemented merely as illustrative of the disclosure and not as a limitation.

### Advantages of the Invention

The present disclosure provides a system and a method that provides support for multiple bandwidths ranging from 40 to 100 Megahertz (MHz) consuming minimal additional resources.

The present disclosure provides a system and a method that re-uses existing field programmable gate array (FPGA) based baseband design with a zero-touch mechanism.

The present disclosure provides a system and a method that requires lesser development effort.

The present disclosure provides a system and a method that uses minimal additional FPGA resources.

The present disclosure provides a system and a method that maintains a uniform sampling rate for all bandwidths to simplify an end to end FPGA design, wherein a Digital Front End (DFE) module in the system incorporates a common up/down sampling of half band filters for different bandwidth configurations.

The present disclosure provides a system and a method where memory consumption is reduced from 22 block random access memory (BRAM) to 2 BRAMs.

The present disclosure optimizes usage of FPGA resources such as look-up tables (LUTs), Flip Flops (FFs), and BRAMs, while making use of the underutilized digital signal processing (DSP) resources and works with a maximum clock frequency up to 491.52 MHz.

We claim:

1. A system (108) for supporting multiple bandwidth, the system (108) comprising:
a processor (202); and
a memory (204) operatively coupled with the processor (202), wherein said memory (204) stores instructions which, when executed by the processor (202), cause the processor (202) to:
generate one or more samples from one or more subcarriers using an Inverse Fast Fourier Transform (IFFT) technique during a modulation stage and using a Fast Fourier Transform (FFT) technique during a de-modulation stage;
compute one or more phase coefficients associated with the one or more subcarriers; and
augment the one or more samples with the one or more phase coefficients to generate a time domain frequency shift associated with the one or more samples for transmission or reception to/from a computing device (104) associated with one or more users (102).

2. The system (108) as claimed in claim 1, wherein the processor (202) is to use a complex multiplier to augment the one or more samples with the one or more phase coefficients during the modulation and de-modulation stages.

3. The system (108) as claimed in claim 1, wherein the processor (202) is to utilize a feed configured bandwidth associated with the one or more phase coefficients to generate the time domain frequency shift associated with the one or more samples.

4. The system (108) as claimed in claim 1, wherein the time domain frequency shift facilitates to support one or more bandwidths associated with the one or more subcarriers.

5. The system (108) as claimed in claim 1, wherein the processor (202) is to generate a quadrant symmetry associated with the one or more phase coefficients to reduce a storage requirement associated with the one or more phase coefficients.

6. The system (108) as claimed in claim 5, wherein the quadrant symmetry is based on an in phase and a quadrature component of the one or more subcarriers.

7. The system (108) as claimed in claim 4, wherein the processor (202) is to maintain a uniform sampling rate across the one or more bandwidths associated with the one or more subcarriers.

8. A method for supporting multiple bandwidth, the method comprising:
generating, by a processor (202) associated with a system (108), one or more samples from one or more subcarriers using an Inverse Fast Fourier Transform (IFFT) technique during a modulation stage and using a Fast Fourier Transform (FFT) technique during a de-modulation stage;
computing, by the processor (202), one or more phase coefficients associated with the one or more subcarriers; and
augmenting, by the processor (202), the one or more samples with the one or more phase coefficients to generate a time domain frequency shift associated with the one or more samples for transmission/reception to/from a computing device (104) associated with one or more users (102).

9. The method as claimed in claim 8, comprising using, by the processor (202), a complex multiplier to augment the one or more samples with the one or more phase coefficients during the modulation and de-modulation stages.

10. The method as claimed in claim 8, comprising utilizing, by the processor (202), a feed configured bandwidth associated with the one or more phase coefficients to generate the time domain frequency shift associated with the one or more samples.

11. The method as claimed in claim 8, comprising generating, by the processor (202), a quadrant symmetry associated with the one or more phase coefficients to reduce a storage requirement associated with the one or more phase coefficients.

12. The method as claimed in claim 11, wherein the quadrant symmetry is based on an in phase and a quadrature component of the one or more subcarriers.

13. The method as claimed in claim 8, comprising maintaining, by the processor (202), a uniform sampling rate across the one or more bandwidths associated with the one or more subcarriers.

14. A user equipment (UE) (104), comprising:
one or more processors communicatively coupled to a processor (202) associated with a system (108), wherein the one or more processors are coupled with a memory, and wherein said memory stores instructions which, when executed by the one or more processors, cause the one or more processors to:
augment one or more modulated samples to generate a time domain frequency shift associated with the one or more modulated samples;
in response to the time domain frequency shift, compute one or more phase coefficients associated with one or more subcarriers; and
generate one or more samples from the one or more subcarriers using a Fast Fourier Transform (FFT) technique during a de-modulation stage and using an Inverse Fast Fourier Transform (IFFT) technique during a modulation stage.

15. A non-transitory computer readable medium comprising a processor with executable instructions, causing the processor to:
generate one or more samples from one or more subcarriers using an Inverse Fast Fourier Transform (IFFT) technique during a modulation stage and using a Fast Fourier Transform (FFT) technique during a de-modulation stage;
compute one or more phase coefficients associated with the one or more subcarriers; and
augment the one or more samples with the one or more phase coefficients to generate a time domain frequency shift associated with the one or more samples for transmission and reception.
